(19) United States
(12) Patent Application Publication
(10) Pub. No.: US 2025/0116684 A1
(43) Pub. Date: Apr. 10, 2025

(54) SEMICONDUCTOR PACKAGE INSPECTION DEVICE

(71) Applicant: SAMSUNG ELECTRONICS CO., LTD., Suwon-si (KR)

(72) Inventors: Hyun YANG, Suwon-si (KR); Sunghyun HONG, Suwon-si (KR)

(21) Appl. No.: 18/890,626

(22) Filed: Sep. 19, 2024

(30) Foreign Application Priority Data
Oct. 6, 2023 (KR) 10-2023-0133692

(51) Int. Cl. G01R 1/04; G01R 31/28

(52) U.S. Cl. CPC G01R 1/0466; G01R 31/2886; G01R 31/2896

(57) ABSTRACT

A semiconductor package inspection device includes a socket block, a plurality of pin holes in the socket block, a plurality of pogo pins in the plurality of pin holes, a sealing portion extending peripherally around a first pin area of the socket block and in which the plurality of pin holes and the plurality of pogo pins are arranged. The sealing portion protrudes from an upper surface of the socket block. The semiconductor package inspection device includes a support socket, an upper test board, and a handler above the upper test board that has an internal vacuum passageway in fluid communication with a vacuum aperture in the upper test board.

### CROSS-REFERENCE TO RELATED APPLICATIONS

This application is based on and claims priority under 35 U.S.C. § 119 to Korean Patent Application No. 10-2023-0133692, filed on Oct. 6, 2023, in the Korean Intellectual Property Office, the disclosure of which is incorporated by reference herein in its entirety.

### BACKGROUND

The inventive concept relates to a semiconductor package inspection device.

An electrical test of a semiconductor package is conducted by handling the semiconductor package by adsorbing a central portion of an upper surface of the semiconductor package by using a vacuum cup.

As input/output (I/O) increases due to the development of semiconductor package technology, connection pads may be provided on the entire upper surface of a semiconductor package, including the central portion of the semiconductor package, and thus handling the semiconductor package by adsorbing the semiconductor package by using a vacuum cup may become difficult.

### SUMMARY

The inventive concept provides a semiconductor package inspection device for stably handling a full-array semiconductor package including connection pads on the entire upper surface thereof and performing an electrical test.

The objective to be solved by the inventive concept is not limited to the objectives mentioned above, and other objectives not mentioned will be clearly understood by those skilled in the art from the description below.

According to an aspect of the inventive concept, there is provided a semiconductor package inspection device including a socket block, a plurality of pin holes extending through the socket block, a plurality of pogo pins, wherein each of the plurality of pogo pins is located within a respective one of the plurality of pin holes, a sealing portion extending peripherally around a first pin area of the socket block, wherein the plurality of pin holes and the plurality of pogo pins are arranged in the first pin area, wherein the sealing portion protrudes from an upper surface of the socket block, a support socket that supports the socket block, an upper test board on an upper surface of the support socket, wherein the upper test board includes a plurality of first contact pads on a bottom surface thereof, and a vacuum aperture formed therethrough, and a handler above the upper test board and having an internal vacuum passageway in fluid communication with the vacuum aperture, wherein each of the plurality of pogo pins includes a pin body, an upper pin protruding upward from the pin body, and a bottom pin protruding downward from the pin body.

According to another aspect of the inventive concept, there is provided a semiconductor package inspection device including a socket block, a plurality of pin holes extending through the socket block, a plurality of pogo pins, wherein each of the plurality of pogo pins is located within a respective one of the plurality of pin holes, a sealing portion extending peripherally around a first pin area of the socket block, wherein the plurality of pin holes and the plurality of pogo pins are arranged in the first pin area, and wherein the sealing portion protrudes from an upper surface of the socket block, a support socket in contact with the socket block and configured to move the socket block in a vertical direction, an upper test board on an upper surface of the support socket, wherein the upper test board includes a plurality of first contact pads on a bottom surface thereof, and a vacuum aperture formed therethrough, and a handler above the upper test board and having an internal vacuum passageway in fluid communication with the vacuum aperture, wherein each of the plurality of pogo pins includes a pin body, an upper pin protruding upward from the pin body, and a bottom pin protruding downward from the pin body, and wherein the sealing portion has a rectangular shape when viewed in a plan view.

According to another aspect of the inventive concept, there is provided a semiconductor package inspection device including a socket block, a plurality of pin holes extending through the socket block, a plurality of pogo pins, wherein each of the plurality of pogo pins is located within a respective one of the plurality of pin holes, a sealing portion extending peripherally around a first pin area of the socket block, wherein the plurality of pin holes and the plurality of pogo pins are arranged in the first pin area, and wherein the sealing portion protrudes from an upper surface of the socket block, a support socket in contact with the socket block and configured to move the socket block in a vertical direction, an upper test board on an upper surface of the support socket, wherein the upper test board has a plurality of first contact pads on a bottom surface thereof, and a vacuum aperture formed therethrough, and a handler above the upper test board and having an internal vacuum passageway in fluid communication with the vacuum aperture, wherein each of the plurality of pogo pins includes a pin body, an upper pin protruding upward from the pin body, and a bottom pin protruding downward from the pin body, wherein each of the plurality of pin holes includes an upper pin hole, a bottom pin hole, and a central pin hole in fluid communication with the upper pin hole and the bottom pin hole, wherein a width of the central pin hole is greater than a width of the pin body, and wherein a width of each of the upper pin hole and the bottom pin hole in which the upper pin and the bottom pin are respectively located, is less than the width of the pin body, wherein a length of the pin body is less than a length of the central pin hole, and wherein a thickness of the socket block is less than a length from an end of the upper pin to an end of the bottom pin when the end of the upper pin and the end of the bottom pin are not in contact with each other, wherein a maximum value of a height of the end of the upper pin protruding from the upper surface of the socket block is less than a height of the sealing portion in an undeformed state, wherein a height of the sealing portion in a deformed state is less than the height of the sealing portion in the undeformed state, and wherein the height of the end of the upper pin protruding from the upper surface of the socket block when the sealing portion is in the deformed state is equal to the height of the sealing portion in the deformed state, and wherein the sealing portion includes an elastic material and has a ring shape when viewed in a plan view, wherein the sealing portion is convexly rounded and protrudes toward the upper test board in a cross-sectional view, and wherein the sealing portion is configured to maintain contact with the bottom surface of the upper test board.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package inspection device according to an embodiment;

FIG. 2 is an enlarged cross-sectional view of a portion of a semiconductor package inspection device, according to an embodiment;

FIG. 3A is a plan view cut along a portion A-A′ of the semiconductor package inspection device according to the embodiment of FIG. 1;

FIG. 3B is a plan view of a semiconductor package inspection device according to an embodiment, cut along a portion identical to portion A-A′ of FIG. 1;

FIG. 3C is a plan view of a semiconductor package inspection device according to an embodiment, cut along a portion identical to portion A-A′ of FIG. 1;

FIG. 4 is a cross-sectional view illustrating a semiconductor package inspection device according to an embodiment;

FIGS. 5A to 5C are cross-sectional views illustrating a process of operating a semiconductor package inspection device according to an embodiment;

FIGS. 6A to 6E are cross-sectional views illustrating a process of operating a semiconductor package inspection device according to an embodiment;

FIGS. 7A to 7C are cross-sectional views illustrating a process of operating a semiconductor package inspection device according to an embodiment;

FIG. 8 is a cross-sectional view illustrating a semiconductor package inspection device according to an embodiment;

FIG. 9A is a plan view of a semiconductor package inspection device according to an embodiment, cut along a portion identical to portion B-B′ of FIG. 8;

FIG. 9B is a plan view of a semiconductor package inspection device according to an embodiment, cut along a portion identical to portion B-B′ of FIG. 8;

FIG. 10 is a cross-sectional view illustrating a semiconductor package inspection device according to an embodiment; and

FIG. 11 is a plan view of a semiconductor package inspection device according to an embodiment, cut along a portion identical to portion C-C′ of FIG. 10.

### DETAILED DESCRIPTION OF THE EMBODIMENTS

Hereinafter, embodiments of the inventive concept will be described in detail with reference to the attached drawings. In the drawings, like elements are labeled like reference numerals and repeated description thereof will be omitted.

In the present embodiment, a case where an inspection object 400 is a semiconductor package provided at the bottom of a package on package (POP) will be described as an example. However, the inventive concept may also be applied to devices for inspecting various types of electronic components having connection terminals formed on an upper surface and a bottom surface thereof, other than semiconductor device packages.

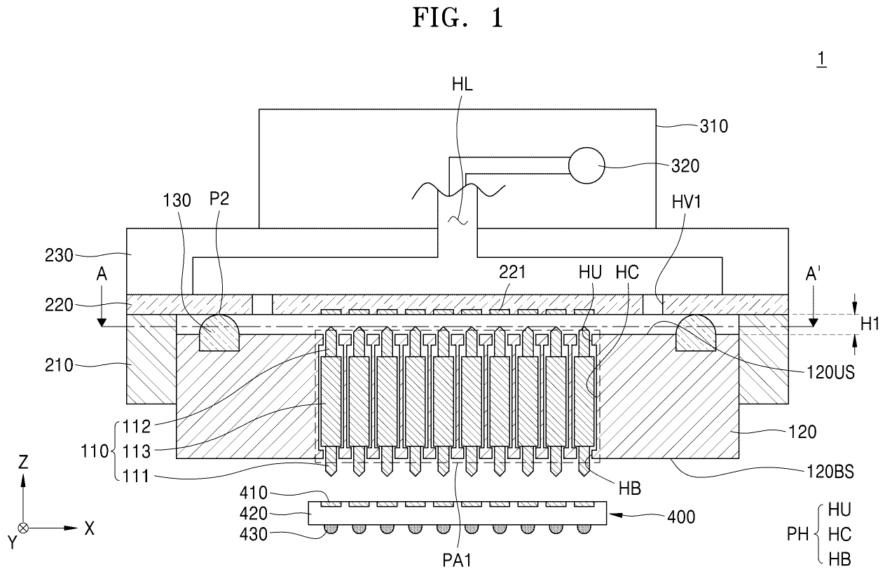

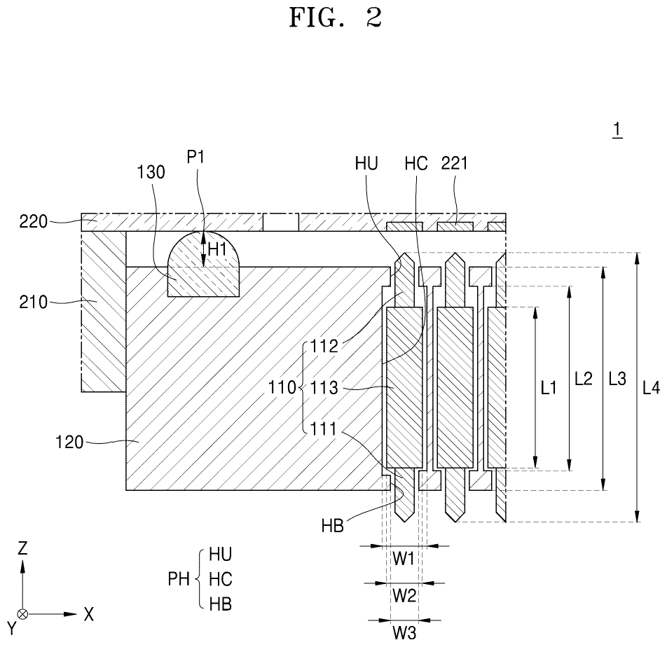

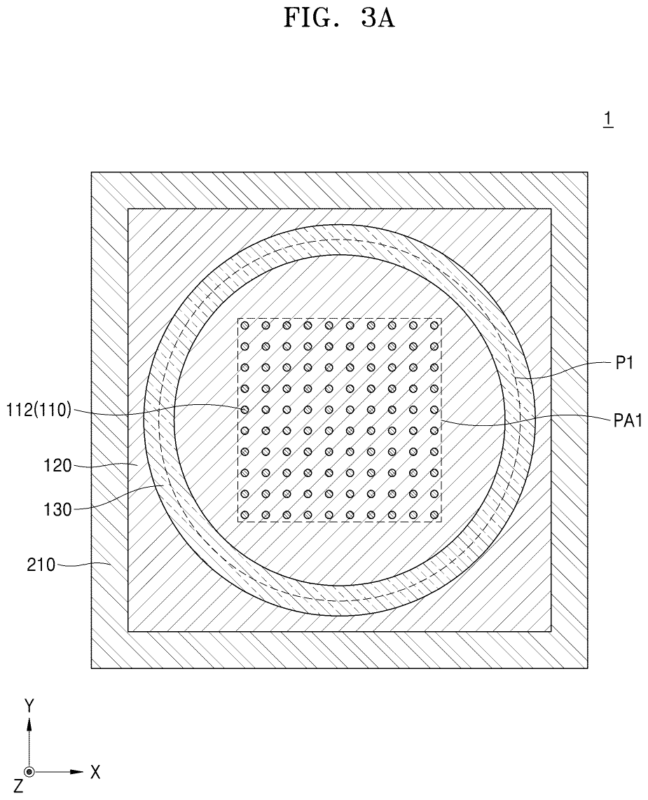

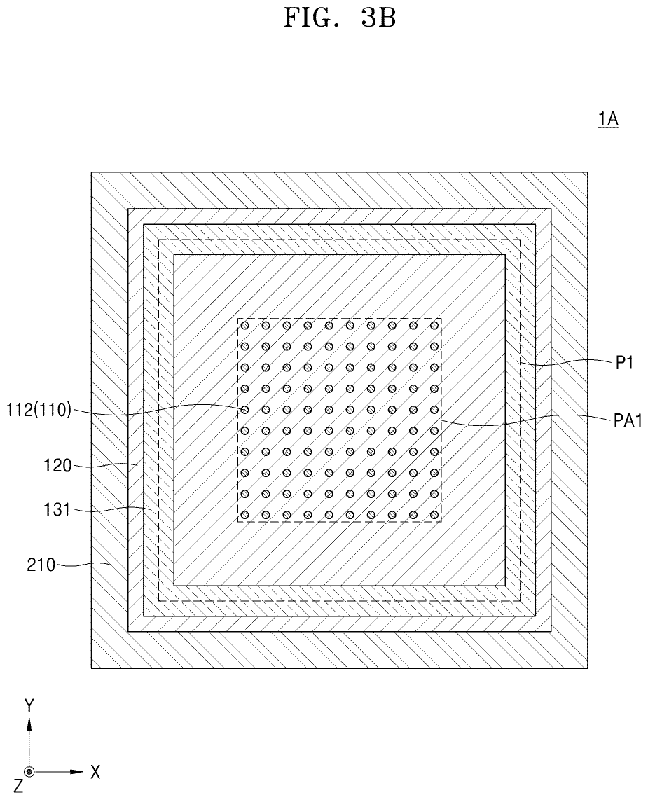

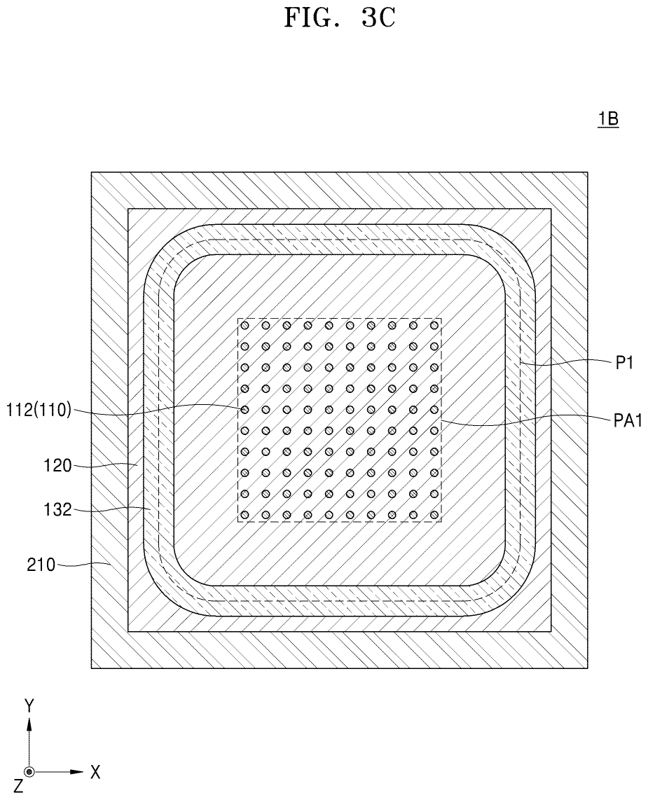

FIG. 1 is a cross-sectional view illustrating a semiconductor package inspection device 1 according to an embodiment. FIG. 2 is an enlarged cross-sectional view of a portion of the semiconductor package inspection device 1, according to an embodiment. FIG. 3A is a plan view cut along a portion A-A′ of the semiconductor package inspection device 1 according to the embodiment of FIG. 1.

Referring to FIGS. 1 to 3A, the semiconductor package inspection device 1 according to an embodiment may include a plurality of pogo pins 110, a socket block 120, a support socket 210, an upper test board 220, a lower handler 230, an upper handler 310, and a negative pressure supply (i.e., vacuum supply) device 320. In this specification, a first direction refers to an X direction in the drawing, a second direction refers to a Y direction in the drawing, and a horizontal plane refers to an XY plane. A third direction refers to a direction perpendicular to both the first direction and the second direction and refers to a Z direction in the drawing.

The upper handler 310 is configured to provide a horizontal movement, a vertical movement, or a rotational movement of the semiconductor package inspection device 1, which is an embodiment, and move the semiconductor package inspection device 1 so as to handle the inspection object 400. Additionally, the negative pressure (i.e., vacuum) supply device 320 supplies negative pressure from the upper handler 310 to an internal negative pressure passage HL of the lower handler 230. In this specification, negative pressure refers to pressure of a target space, which is lower than pressure of the space surrounding the semiconductor package inspection device, which is an embodiment. In this specification, supply of negative pressure indicates that, through the intake of the air (or other gas) by the negative pressure supply device 320, the pressure of the target space becomes lower than the pressure of the space surrounding the semiconductor package inspection device. The terms “negative pressure” and “vacuum” are interchangeable as used herein. In this specification, a handler may collectively refer to the upper handler 310 and the lower handler 230.

The internal vacuum passageway HL may vertically penetrate the upper test board 220 and communicate with at least one first vacuum hole or aperture HV1. Through the first vacuum aperture HV1, the vacuum supplied from the vacuum supply device 320 may be supplied to an internal area surrounded by the socket block 120, a sealing portion 130, and the upper test board 220. Additionally, a vacuum supplied through the first vacuum aperture HV1 may be supplied to a plurality of pin holes PH included in the socket block 120, as described below. Since the plurality of pin holes PH vertically penetrate the socket block 120, vacuum may be transmitted to the outside through the plurality of pin holes PH and a plurality of bottom pin holes HB.

When the inspection object 400 is in contact with a bottom surface 120BS of the socket block 120 provided with the plurality of bottom pin holes HB and vacuum is supplied, an upper surface of the inspection object 400 may be adsorbed (i.e., removably secured or attached) to the bottom surface 120BS of the socket block 120. When the upper surface of the inspection object 400 is removably attached to the bottom surface 120BS of the socket block 120, a force directed vertically upward may be received from the upper surface of the inspection object 400. Among the upper pins 112 of the plurality of pogo pins 110 that have received a vertically upward force, some upper pins 112 are inserted into a pin body 113, and the exposed length of the upper pins 112 of the plurality of pogo pins 110 may be shortened.

Through the above-described process, the semiconductor package inspection device 1, which is an embodiment, may adsorb the inspection object 400 through vacuum and stably handle the same to a required position.

The socket block 120 may include the plurality of pin holes PH in which the plurality of pogo pins 110 are included, respectively. The plurality of pogo pins 110 may each include the pin body 113, the upper pin 112 protruding upward from the pin body 113, and the bottom pin 111 protruding upward from the pin body 113.

Each of the plurality of pogo pins 110 may include an elastic body (not shown) therein. The elastic body may be provided inside the pin body 113, and the upper pin 112 and the bottom pin 111 may be connected to the elastic body and provided on upper and bottom surfaces of the pin body 113. The elastic body may apply upward and downward elastic forces to the upper pin 112 and the bottom pin 111, respectively (i.e., the elastic body acts as a biasing member that is configured to urge the upper pin 112 and the bottom pin 111 respectively outward from the pin body 113).

When a force is applied vertically downward to the upper pin 112 while the pin body 113 is in contact with and fixed to a bottom surface of a central pin hole HC, a portion of the upper pin 112 is depressed into the inside of the pin body 113, and thus, the length of the upper pin 112 protruding vertically upward from the pin body 113 may be shortened. Likewise, when a force is applied vertically upward to the bottom pin 111 while the pin body 113 is fixed in contact with an upper surface of a central pin hole HC, a portion of the bottom pin 111 is depressed into the inside of the pin body 113, and thus, the length of the bottom pin 111 protruding vertically downward from the pin body 113 may be shortened.

The plurality of pin holes PH may include the plurality of pogo pins 110 therein, respectively. The plurality of pin holes PH may include an upper pin hole HU, the bottom pin hole HB, and the central pin hole HC. The upper pin hole HU may have a width that passes through the upper pin 112 but does not pass through the pin body 113. The bottom pin hole HB may have a width that passes through the bottom pin 111 but does not pass through the pin body 113. The upper pin hole HU may communicate with the central pin hole HC at an upper surface 120US of the socket block 120, and the bottom pin hole HB may communicate with the central pin hole HC at a bottom surface 120UB of the socket block 120.

In other words, as in FIG. 2, a third width W3, which is a horizontal width of each of the upper pin hole HU and the bottom pin hole HB, may be greater than a horizontal width of each of the bottom pin 111 and the horizontal width of the upper pin 112. However, the third width W3 may be less than a second width W2, which is a horizontal width of the pin body 113. Accordingly, the upper pin 112 and the bottom pin 111 may be moved through the upper pin hole HU and the bottom pin hole HB, respectively, but the pin body 113 may be configured not to pass through the upper pin hole HU and the bottom pin hole HB.

The plurality of pogo pins 110 may each be moved by a certain length in the third direction within the plurality of pin holes PH. That is, as illustrated in FIG. 2, a first length L1, which is a vertical length of the pin body 113, may be less than a second length L2, which is a vertical length of the central pin hole HC. Accordingly, the plurality of pogo pins 110 may each be moved in a vertical direction by the difference between the first length L1 and the second length L2.

In order that the plurality of pogo pins 110 may be moved up and down without significant obstruction, the horizontal width of each of the bottom pins 111 and the upper pin 112 may be greater than the first width W1 which is the horizontal width of the central pin hole HC. Additionally, the first width W1 may be greater than the second width W2 so that the plurality of pogo pins 110 may be moved up and down without significant obstruction.

However, as described below, the first width W1 may be greater than the second width W2, but not excessively greater, in order that vacuum may be appropriately applied to the upper surface of the inspection object 400 to be attached to the lower side of the socket block 120 through the plurality of pin holes PH. Likewise, the horizontal width of each of the upper pin 112 and the bottom pin 111 may be less than the third width W3, but should not be excessively less than the third width W3. In an embodiment, the difference between the first width W1 and the second width W2 may be about 0.05 mm to about 0.2 mm. The difference between the horizontal width of each of the upper pins 112 and the bottom pins 111 and the third width W3 may be about 0.05 mm to about 0.2 mm. However, the difference between the first width W1 and the second width W2 and the difference between the horizontal width of each of the upper pin 112 and the bottom pin 111 and the third width W3, respectively, may be determined based on the number of pogo pins 110 and the number of pin holes PH provided in the socket block 120 of the semiconductor package inspection device 1, which is an embodiment, and the horizontal area of the inspection object 400, or the like, and are not limited by the values given as examples.

As illustrated in FIG. 2, a third length L3, which is a vertical distance from the upper surface 120US of the socket block 120 to the bottom surface 120BS of the socket block 120, may be less than a fourth length L4, which is a vertical length from an end of the upper pin 112 to an end of the bottom pin 111 of each of the plurality of pogo pins 110 that are not shortened because the upper pin 112 and the bottom pin 111 are not in contact with the upper test board 220 and the inspection object 400. The third length L3 may refer to a vertical thickness of the socket block 120. The fourth length L4 is greater than the third length L3 in order that first contact pads 221 disposed on a bottom surface of the upper test board 220, as described below, and, a plurality of pogo pins 110 corresponding to the first contact pads 221 are electrically in contact with each other, and at the same time, contact pads 410 disposed on an upper surface of an object body 420 of the inspection target 400 and the plurality of pogo pins 110 are in contact with and electrically connected to each other.

The sealing portion 130 that protrudes vertically upward from the upper surface 120US of the socket block 120 may be provided on the upper surface 120US of the socket block 120. The sealing portion 130 may be in contact with the upper surface of the upper test board 220. With respect to a first point P1, which is a central point where the upper test board 220 and the sealing portion 130 contact each other, as a boundary, the sealing portion 130 may prevent leakage of vacuum supplied to a space surrounded by the bottom surface of the upper test board 220, the sealing portion 130, and the upper surface 120US of the socket block 120.

A vertical cross-section of the sealing portion 130 may be convexly rounded and protrude toward the upper test board 220. For example, a cross-sectional shape of a protruding portion of the sealing portion 130 from the upper surface 120US of the socket block 120 may be an upwardly protruding semi-elliptical shape.

In this specification, a central area of the socket block 120 where the plurality of pin holes PH and the plurality of pogo pins 110 are disposed may be referred to as a first pin area PA1. The first pin area PA1 may be defined as an area as illustrated in FIGS. 1 and 3A to 3C, which is spaced apart from the outer edge of the socket block 120 and in which the plurality of pin holes PH and the plurality of pogo pins 110 are included. In an embodiment, since the plurality of pin holes PH and the plurality of pogo pins 110 are densely packed in a square shape in a plane view, the first pin area PA1 may also have a square shape in a plane view. However, the dense arrangement of the plurality of pin holes PH and the plurality of pogo pins 110 and the shape of the first pin area PA1 are not limited to the illustrated configuration.

The sealing portion 130 may be provided in the upper surface 120US of the socket block 120. For example, the sealing portion 130 may be embedded in the upper surface 120US of the socket block 120 and may be provided to protrude vertically upward from the upper surface 120US of the socket block 120, as illustrated in FIGS. 1 and 2. Alternatively, unlike in FIGS. 1 and 2, the sealing portion 130 may be attached to the upper surface 120US of the socket block 120.

The sealing portion 130 may extend peripherally around the first pin area PA1, and may be spaced apart from the first pin area PA1 and also from the outer edge of the socket block 120, and may be located on the upper surface 120US of the socket block 120. For example, as illustrated in FIG. 3A, the shape of the sealing portion 130 may be a ring or circular shape that extend peripherally around the first pin area PA1 when viewed in plan view. Since the shape of the sealing portion 130 is a ring or circular shape, the shape of the first point P1 when viewed in plan view, which is the center point where the upper test board 220 and the sealing portion 130 contact each other, may also be circular as marked by a dashed line in FIG. 3A. In order to maintain vacuum in an inner region of the sealing portion 130 where the first pin area PA1 is located with respect to the sealing portion 130, in the sealing portion 130, an outer region of the sealing portion 130 which is between the sealing portion 130 and the support socket 210 and the inner region of the sealing portion 130 may be distinguished from each other. The sealing portion 130 may prevent communication between the outer region and the inner region with respect to the sealing portion 130. Alternatively, an upper end of the sealing portion 130 may be attached to the upper test board 220. Accordingly, the outer region and the inner region may be distinguished and separated from each other.

The support socket 210 may be configured to contact a side of the socket block 120 so that the socket block 120 may move in a vertical direction with respect to the support socket 210. The support socket 210 may be provided along the outer edge of the bottom surface of the upper test board 220, or, unlike in the drawing, may be arranged such that the upper test board 220 meets the inner side of the support socket 210.

The lower handler 230 having an internal vacuum passageway HL may be provided on the upper test board 220. The lower handler 230 may be connected along the side of the upper test board 220 and communicate with the internal vacuum passageway HL and the first vacuum aperture HV1 provided in the upper test board 220. The internal vacuum passageway HL may be formed even in the upper handler 310.

The sealing portion 130 may be deformed due to force applied from the surroundings. That is, between the socket block 120, in which the sealing portion 130 is disposed, and the upper test board 220, the sealing portion 130 may be deformed by a force transmitted from the upper handler 310 and the lower handler 230. The sealing portion 130 may include an elastic material. For example, the sealing portion 130 may include a material including silicon, resin, rubber, etc., which have elasticity.

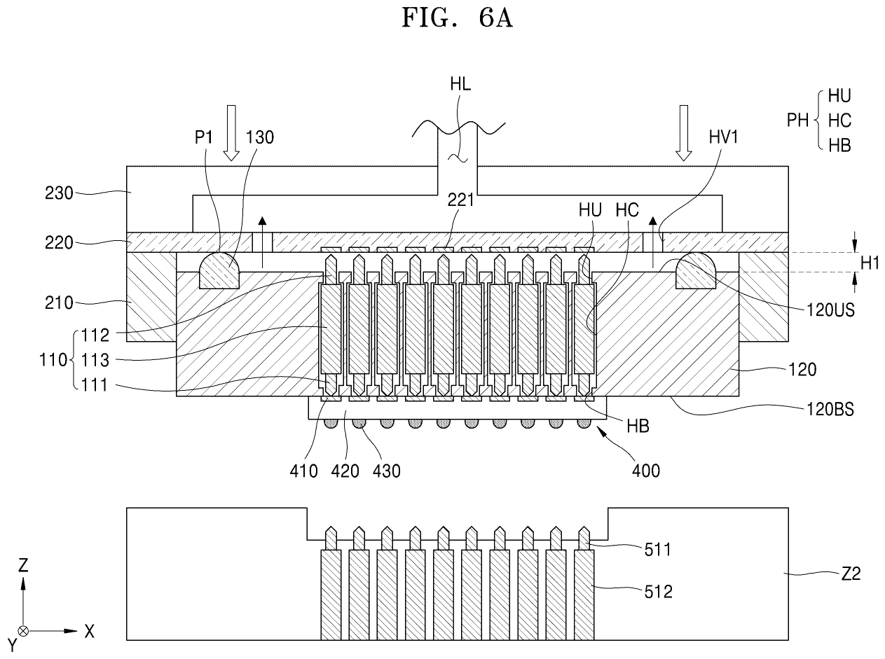

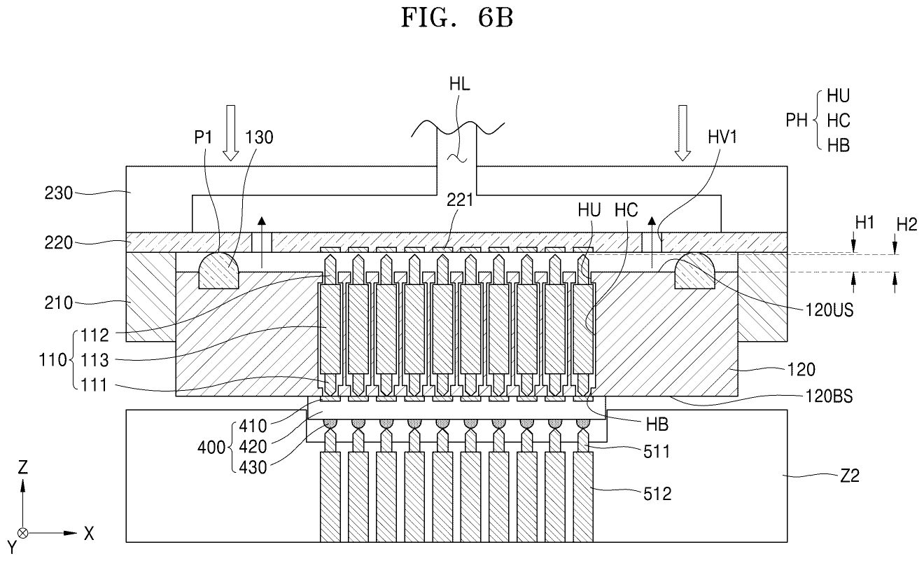

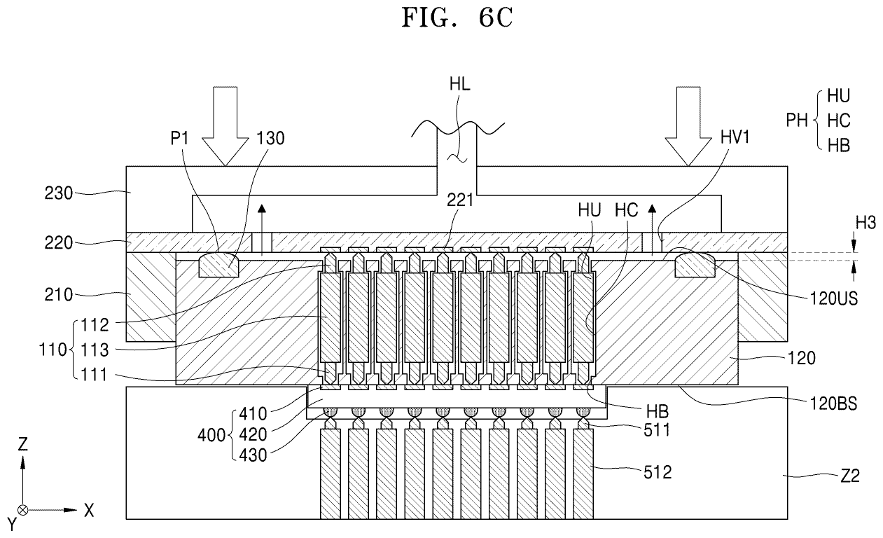

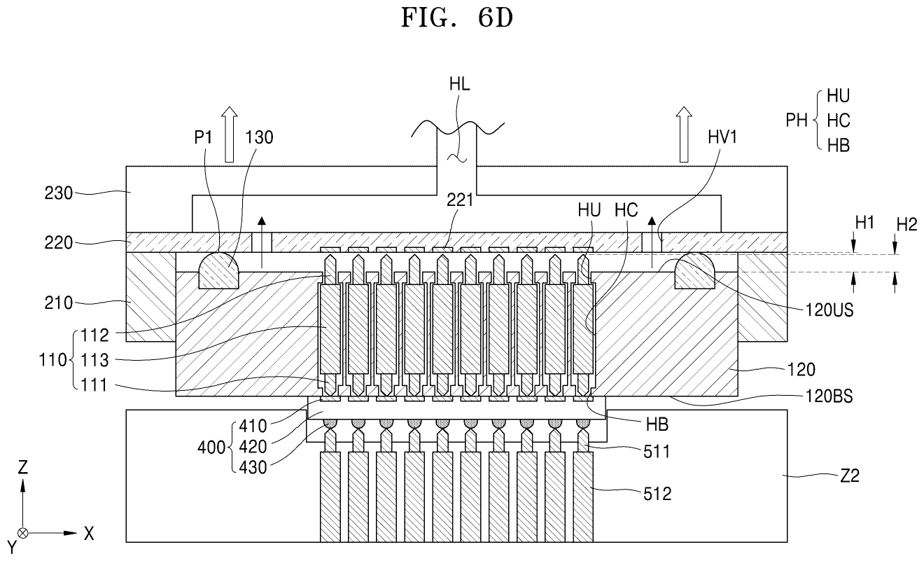

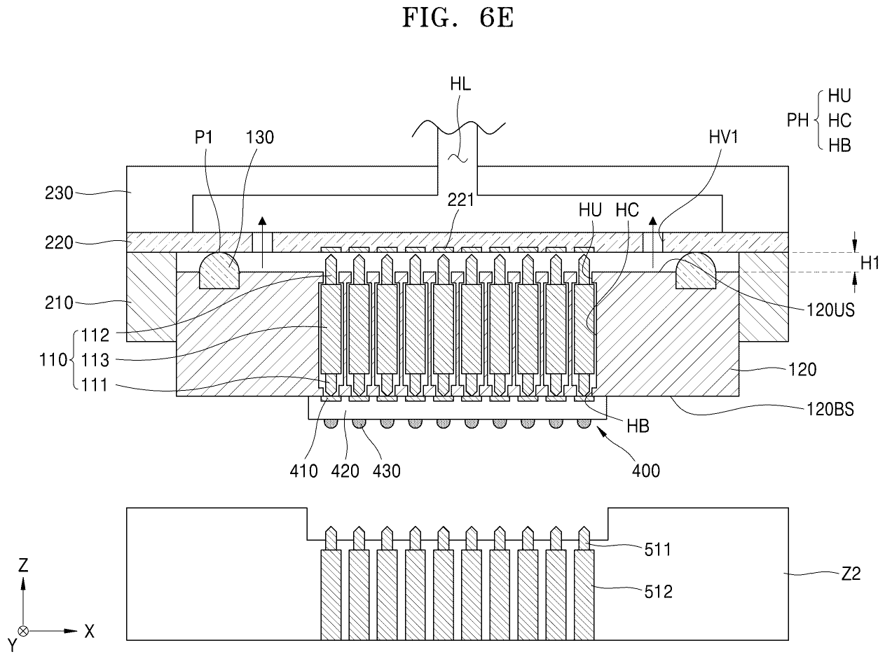

The semiconductor package inspection device 1, which is an embodiment, is described below with reference to FIGS. 6B and 6C. A first height H1, which is a vertical height of the sealing portion 130 that is in an undeformed state and protrudes from the upper surface 120US of the socket block 120, may be greater than the maximum value of a second height H2, which is a vertical height of the upper pin 112 of each of the plurality of pogo pins 110, the upper pin 112 protruding from the upper surface 120US of the socket block 120. The second height H2 is a value that may vary depending on the degree to which the upper pin 112 protrudes from the upper surface 120US of the socket block 120.

For example, as illustrated in FIG. 6B, when the inspection object 400 is removably attached to the bottom surface 120BS of the socket block 120, the plurality of pogo pins 110 may contact corresponding contact pads 410 provided on the upper surface of the inspection object 400, and at the same time, the pogo pins 110 may be pushed up by the inspection object 400. As the pin body 113 reaches the uppermost surface of the plurality of pin holes PH, the upper pin 112 may protrude from the upper surface 120US of the socket block 120 to the maximum. Here, the vertical height of the upper pins 112 of the plurality of pogo pins 110, the upper pins 112 protruding from the upper surface 120US of the socket block 120 to the maximum, may be the maximum value of the second height H2. When the sealing portion 130 is not deformed, the upper pin 112 of each of the plurality of pogo pins 110 does not contact the first contact pads 221.

The first height H1 is greater than the maximum value of the second height H2 in order to prevent the plurality of pogo pins 110 from contacting the first contact pads 221 provided on the bottom surface of the upper test board 220 in a process in which the semiconductor package inspection device 1 according to an embodiment handles the inspection object 400. In this specification, handling refers to moving and arranging of the inspection object 400 by the semiconductor package inspection device, which is an embodiment.

The first height H1 may be equal to or less than a vertical height between the bottom surface of the upper test board 220 and the upper surface 120US of the socket block 120. When the first height H1 and the vertical height between the bottom surface of the upper test board 220 and the upper surface 120US of the socket block 120 are equal, the sealing portion 130 is in contact with the bottom surface of the upper test board 220. An upper end of the sealing portion 130 may be connected to the bottom surface of the upper test board 220 and remain attached thereto. Alternatively, the support socket 210 and the socket block 120 may be configured such that the support socket 210 limits the vertical movement of the socket block 120 so that the upper end of the sealing portion 130 does not separate from the bottom surface of the upper test board 220.

The sealing portion 130 may be deformed by receiving a downward force. For example, as illustrated in FIG. 6C, the inspection object 400 may be removably attached to the bottom surface 120BS of the socket block 120, and at the same time, the bottom surface 120BS of the socket block 120 may contact an upper surface of a second socket Z2 on which the inspection object 400 is located. While the bottom surface 120BS of the socket block 120 is in contact with the upper surface of the second socket Z2 where the inspection object 400 is located, an upper pin 511 of each of a plurality of lower pogo pins 512 provided in the second socket Z2 may be pressed to shorten the upper pin 511. A detailed description of this is provided below with reference to FIGS. 6A to 6C.

As a downward force transmitted by the upper handler 310 and the lower handler 230 is applied, the third height H3, which is the vertical height of the sealing portion 130 which is in the most deformed state and protrudes from the upper surface 120US of the socket block 120, may be equal to the second height when the sealing portion 130 is in the most deformed state. That is, a height of the plurality of upper pins 112 each protruding from the upper surface 120US of the socket block 120 may be equal to the vertical height of the sealing portion 130, which is in the most deformed state and protrudes from the upper surface 120US of the socket block 120. Expressed differently, the plurality of upper pins 112 are in contact with the bottom surface of the upper test board 220, and thus, the plurality of upper pins 112 are in contact with the corresponding first contact pads 221 provided on the bottom surface of the upper test board 220. The corresponding first contact pads 221 provided on the bottom surface of the upper test board 220 may be portions of pads or wires provided on the upper test board 220.

The inspection object 400 may be removably attached to the bottom surface 120BS of the socket block 120 through vacuum and handled by the semiconductor package inspection device 1. If a downward force is not applied to the socket block 120, the plurality of pogo pins 110 and the upper test board 220 do not electrically contact each other. When a downward force is applied to the socket block 120 that is in contact with the inspection object 400, the sealing portion 130 is deformed and the upper test board 220 and the plurality of pogo pins 110 may contact each other and be electrically connected to each other. At the same time, the downward force applied to the socket block 120 may be transmitted to the inspection object 400, so that an external connection terminal 430 disposed under the object body 420 may contact the upper pin 511 of each of the plurality of lower pogo pins 512 therebelow and electrically connected thereto. That is, the upper test board 220, the plurality of pogo pins 110, the inspection object 400, and the plurality of lower pogo pins 512 may be electrically connected to each other. Accordingly, an electrical test may be performed on the inspection object 400. The electrical test may be a process of determining the electrical characteristics and defects of the inspection object 400.

As described above, the inspection object 400 may be handled stably through vacuum. In addition, the electrically connected configuration changes depending on the deformation of the sealing portion 130, and an electrical test may be performed by deforming the sealing portion 130 by applying a downward force to the sealing portion 130. Thus, the semiconductor package inspection device 1, which is an embodiment, adsorbs and stably handles a full-array semiconductor package including connection pads that are provided on the entire upper surface thereof, and an electrical test of the full-array semiconductor package may be performed through the semiconductor package inspection device 1.

FIG. 3B is a plan view of a semiconductor package inspection device 1A according an embodiment, cut along a portion identical to portion A-A′ of FIG. 1. FIG. 3C is a plan view of a semiconductor package inspection device 1B according an embodiment, cut along a portion identical to portion A-A′ of FIG. 1. Descriptions within the scope that overlap with the descriptions provided above may be omitted.

Referring to FIG. 3B, a sealing portion 131 of the semiconductor package inspection device 1A, which is an embodiment, may be around the first pin area PA1, and may be spaced apart from the first pin area PA1, and be spaced apart also from the outer edge of the socket block 120 and provided on the upper surface 120US of the socket block 120. For example, as illustrated in FIG. 3B, the shape of the sealing portion 131 when viewed in plan view may be a frame or rectangular shape with the first pin area PA1 in a center. Since the shape of the sealing portion 131 is rectangular, the shape of the first point P1 when viewed in the plan view, which is a center point where the upper test board 220 and the sealing portion 131 contact each other, may also be rectangular (e.g., square), and is marked by a dashed line in FIG. 3B. In order to maintain vacuum in an inner region of the sealing portion 131 where the first pin area PA1 is located with respect to the sealing portion 131, in the sealing portion 131, an outer region of the sealing portion 131, which is between the sealing portion 131 and the support socket 210 and the inner region of the sealing portion 131, may be distinguished from each other, and communication between the outer region and the inner region may be prevented by the sealing portion 131. Alternatively, the upper end of the sealing portion 131 may be attached to the upper test board 220. Accordingly, the outer region and the inner region may be distinguished and separated from each other.

In the semiconductor package inspection device 1A, which is an embodiment, the area required to provide the sealing portion 131 for sealing is relatively small compared to the case where the shape of the sealing portion 130 in plan view described above is a ring or circular shape, the semiconductor package inspection device 1A may be selected when the horizontal area of the first pin area PA1 is relatively large and a distance between the first pin area PA1 and the outer edge of the socket block 120 is relatively small.

Referring to FIG. 3C, a sealing portion 132 of the semiconductor package inspection device 1B, which is an embodiment, is illustrated, and for example, as in FIG. 3C, the shape of the sealing portion 132 when viewed in plan view may be a frame or rectangular shape which includes the first pin area PA1 in a center and has rounded vertices (i.e., corners). Since the shape of the sealing portion 132 in plan view is a frame or rectangular shape with rounded corners, the shape of the first point P1 in plan view, which is a center point where the upper test board 220 and the sealing portion 132 contact each other, may also be rectangular (e.g., square) with rounded corners, and is indicated by a dashed line in FIG. 3C.

The semiconductor package inspection device 1B, which is an embodiment, may include the sealing portion 132 including rounded vertices of the frame shape, unlike the case where the shape of the sealing portion 131 described above is rectangular in plan view. Thus, compared to the sealing portion 131 having a frame shape and including vertices at right angles, the sealing portion 132, of which frame-shaped vertices are rounded is less likely to leak vacuum. Accordingly, the vacuum in the inner region of the sealing portion 132 where the first pin area PA1 is located with respect to the sealing portion 132 may be maintained easily and reliably.

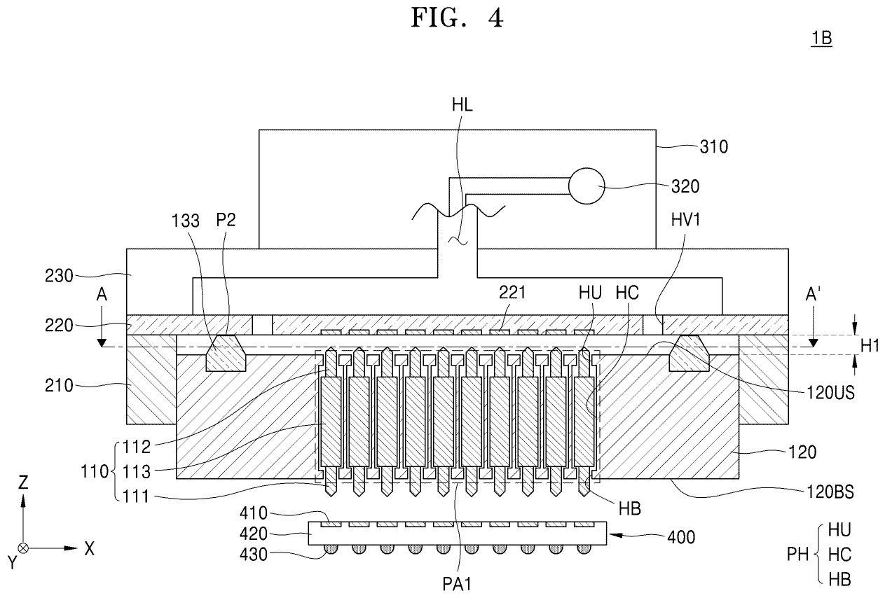

FIG. 4 is a cross-sectional view illustrating a semiconductor package inspection device 1C according to an embodiment. Descriptions within the scope that overlap with the descriptions provided above may be omitted.

Referring to FIG. 4, at least a portion of a vertical cross-sectional shape of a sealing portion 133 included in the semiconductor package inspection device 1C, which is an embodiment, may be a tapered shape having a horizontal width that decreases away from the socket block 120. For example, as illustrated in FIG. 4, a portion of the sealing portion 133 protruding upward from the upper surface 120US of the socket block 120 may have a tapered shape as described above, and a portion of the sealing portion 133 embedded in the socket block 120 may have a shape having a horizontal width that does not change. A portion of the sealing portion 133 that contacts the upper test board 220 may be flat or planar rather than a point. Accordingly, an internal second point P2 that distinguishes an inner region from an outer region of the sealing portion 133, wherein the inner region and the outer region are distinguished by the sealing portion 133, may be an extending plane rather than a point that is in contact with the upper test board 220.

In the semiconductor package inspection device 1B, which is an embodiment, a vertical cross-sectional shape of the sealing portion 133 is tapered, and the portion where the sealing portion 133 contacts the upper test board 220 is planar, and thus the sealing portion 133 may change stably due to an external force, and the degree of deformation of the sealing portion 133 may be uniform even when a relatively large external force is applied to the sealing portion 133.

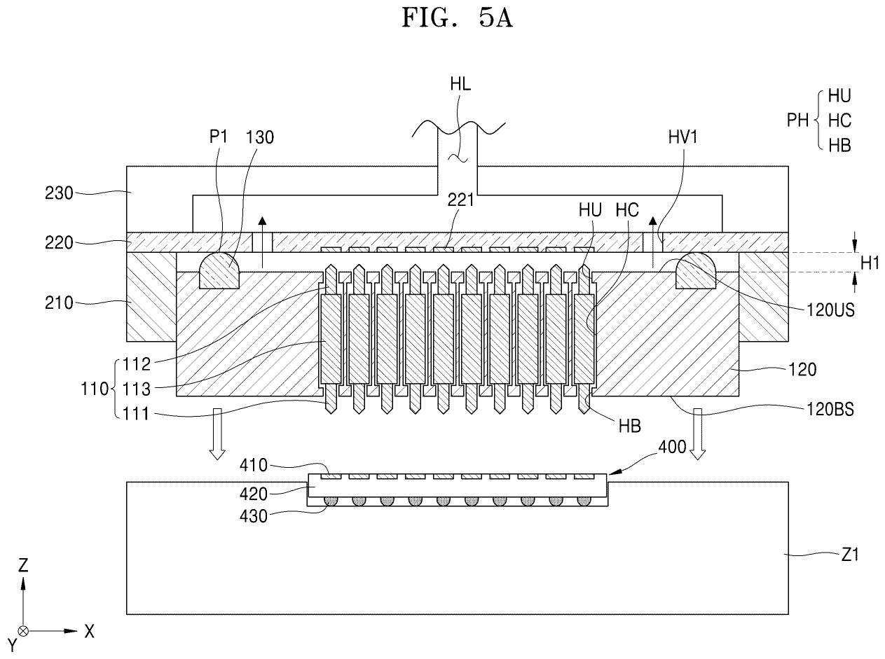

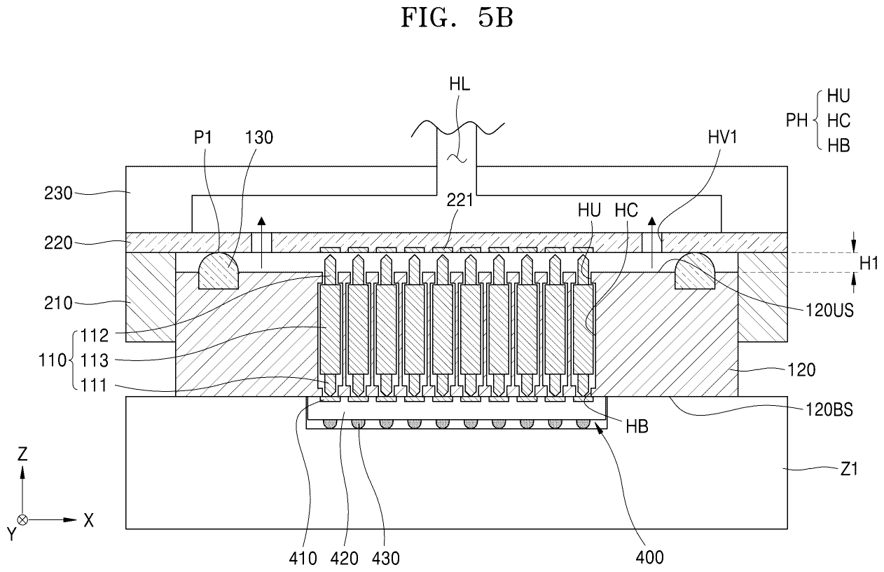

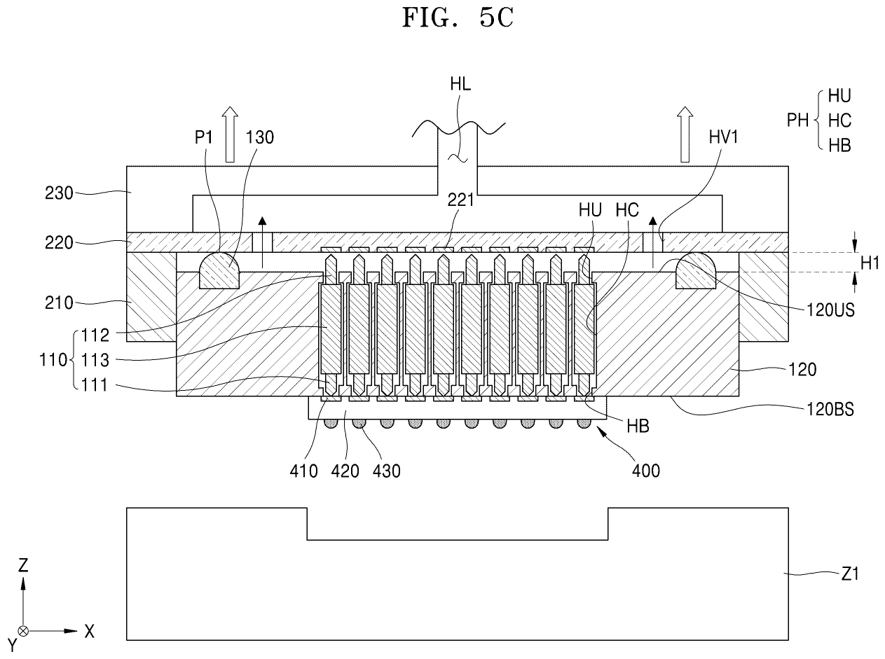

FIGS. 5A to 5C are cross-sectional views illustrating a process of operating the semiconductor package inspection device 1, according to an embodiment. Specifically, FIGS. 5A to 5C illustrate a process in which the semiconductor package inspection device 1, which is an embodiment, lifts the inspection object 400 from a first socket Z1. Descriptions within the scope that overlap with the descriptions provided above may be omitted.

Referring to FIGS. 5A to 5C, the semiconductor package inspection device 1 may move to the inspection object 400 arranged in the first socket Z1. The first socket Z1 may be a place where the inspection object 400 for which the process has been completed is located. The semiconductor package inspection device 1 may move to a portion that is vertically above the inspection object 400 to be lifted, and descend toward the inspection object 400 located below the semiconductor package inspection device 1. Before or after the bottom surface 120BS of the socket block 120 of the semiconductor package inspection device 1 that is lowered contacts the upper surface of the inspection object 400, vacuum is supplied through the internal vacuum passageway HL. In FIGS. 5A to 5C, the vacuum is schematically illustrated as an arrow pointing upward through the first vacuum aperture HV1. Vacuum may act on the upper surface of the inspection object 400 through the first vacuum aperture HV1. Accordingly, the inspection object 400 may be removably attached to the bottom surface 120BS of the socket block 120.

Due to the inspection object 400 being attached to the bottom surface 120BS of the socket block 120, the bottom pins 111 of the plurality of pogo pins 110 may be pushed up. However, as described above, since the sealing portion 130 is not deformed, even if the plurality of pogo pins 110 are pushed upward due to the inspection object 400, the plurality of upper pins 112 and the first contact pads 221 disposed on the bottom surface of the upper test board 220 do not contact each other.

FIGS. 6A to 6E are cross-sectional views illustrating a process of operating the semiconductor package inspection device 1, according to an embodiment. Specifically, FIGS. 6A to 6E illustrate a process in which the semiconductor package inspection device 1, which is an embodiment, performs an electrical test by inserting the inspection object 400 into a second socket Z2. Descriptions within the scope that overlap with the descriptions provided above may be omitted.

Referring to FIG. 6A, the semiconductor package inspection device 1 may transport the inspection object 400 to a portion that is vertically above the second socket Z2 to perform an electrical test. Like FIG. 5C, the inspection object 400 may be maintained in a state of being attached to the bottom surface 120BS of the socket block 120 through the vacuum supplied through the internal vacuum passageway HL.

Referring to FIG. 6B, the semiconductor package inspection device 1 may move downward toward the second socket Z2 and contact the upper pin 511 of each of the plurality of lower pogo pins 512 corresponding to a plurality of external terminals 430 disposed in a lower portion of the inspection object 400 provided in the second socket Z2. As illustrated in FIG. 6B, even if the plurality of external connection terminals 430 and the corresponding plurality of lower pogo pins 512 contact each other, if no sufficient downward force is applied to the sealing portion 130 and the sealing portion 130 is not deformed, the first contact pads 221 and the plurality of pogo pins 110 corresponding thereto are not electrically connected to each other.

The plurality of upper pins 112 protruding from the upper surface 120US of the socket block 120 may be pressed downward while being in contact with the upper test board 220. A portion of each of the plurality of upper pins 112 may enter the interior of each pin body 113, thereby shortening the exposed length of the plurality of upper pins 112. Due to the downward force received when the plurality of upper pins 112 are in contact with the upper test board 220, a portion of the plurality of bottom pins 111 may enter the interior of each pin body 113, and the exposed length of the plurality of bottom pins 111 may be shortened.

In this case, the upper test board 220, the plurality of pogo pins 110, the inspection object 400, and the plurality of lower pogo pins 512 may be electrically connected to each other. Thus, when the force applied downward is maintained, the electrical connection between the upper test board 220, the inspection object 400, and the plurality of lower pogo pins 512 is maintained, and thus an electrical test on the inspection object 400 may be performed.

Referring to FIG. 6D, the electrical test is completed and the downward force may be removed. When the downward force is removed, the sealing portion 130 is restored to its original state, and due to the elastic force, the contact between the upper pins 112 of the plurality of pogo pins 110 and the first contacts pads 221 provided on the bottom surface of the upper test board 220 may be released. As illustrated in FIG. 6D, even if the inspection object 400 is attached to the bottom surface 120BS of the socket block 120, the first height H1 may be greater than the second height H2, which is the vertical height of the upper pin 112 of each of the plurality of pogo pins 110, the upper pin 112 protruding from the upper surface 120US of the socket block 120.

Referring to FIG. 6E, the inspection object 400 on which the electrical test has been completed may be transported to a next location while maintaining the inspection object 400 attached to the bottom surface 120BS of the socket block 120.

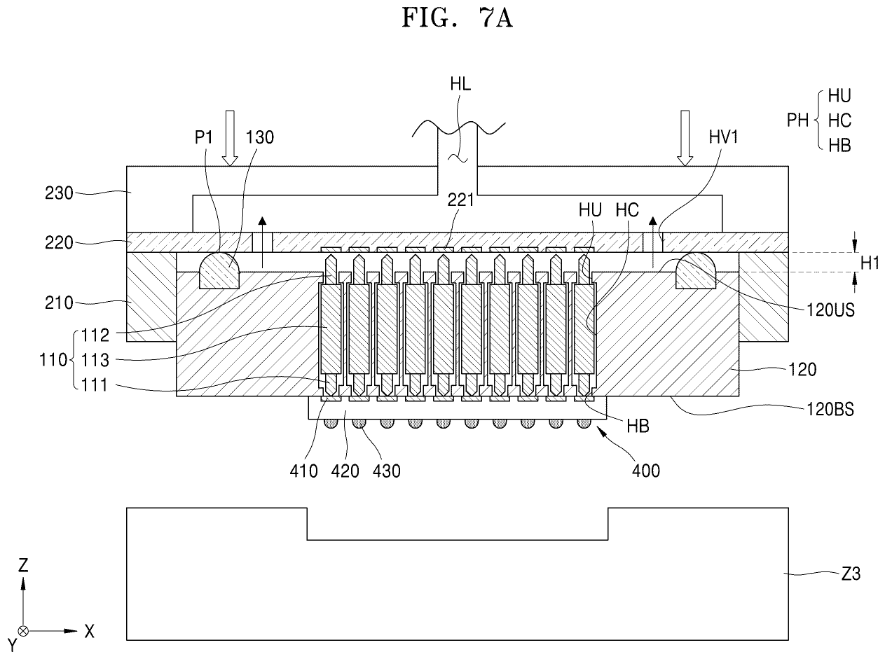

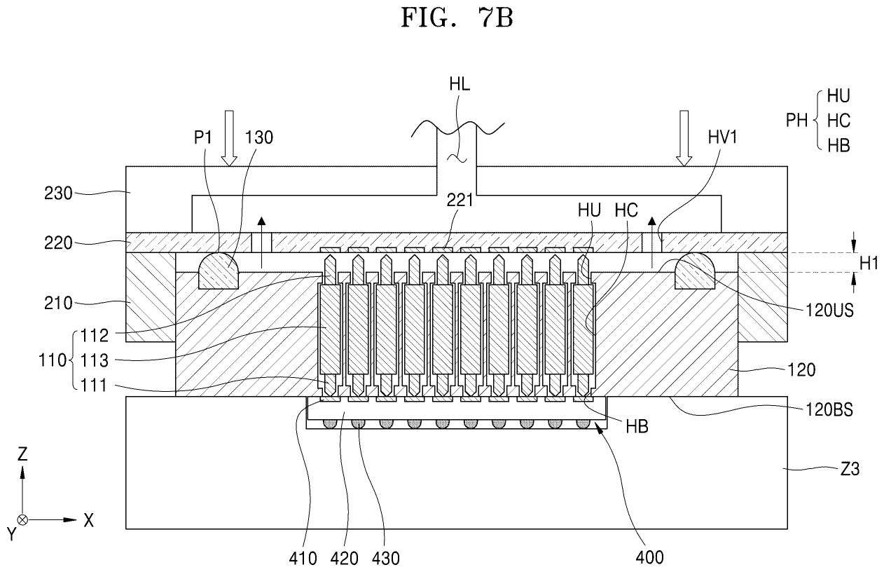

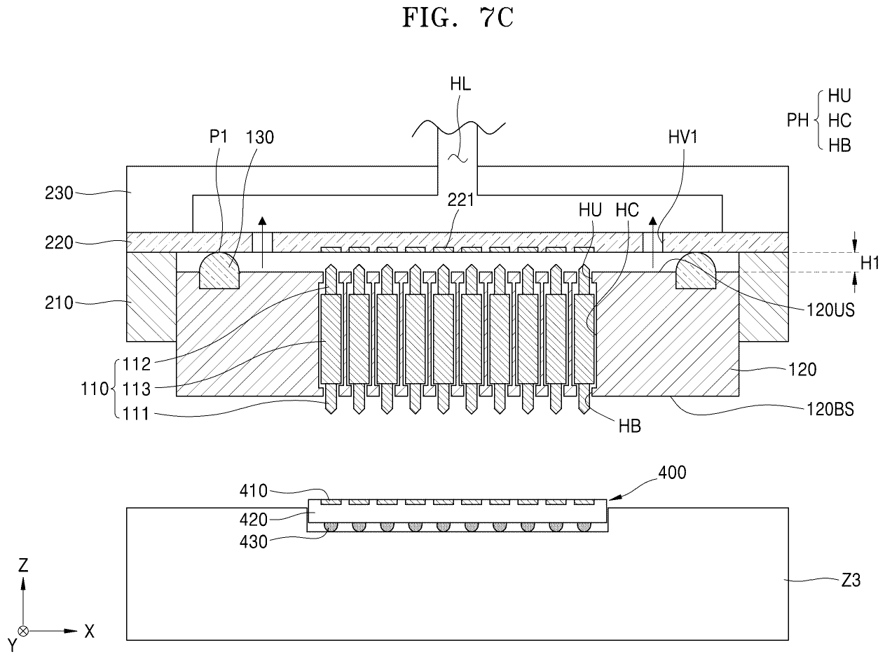

FIGS. 7A to 7C are cross-sectional views illustrating a process of operating the semiconductor package inspection device 1, according to an embodiment. In detail, FIGS. 7A to 7C illustrate a process in which the semiconductor package inspection device 1, which is an embodiment, puts down the inspection object 400 on the third socket Z3. Descriptions within the scope that overlap with the descriptions provided above may be omitted.

Referring to FIGS. 7A to 7C, the inspection object 400 may be placed on the third socket Z3 in the reverse order to the process described with reference to FIGS. 5A to 5C. The semiconductor package inspection device 1 may transport the inspection object 400 to different locations depending on whether the inspection object 400 is a good product. For example, the third socket Z3 in FIGS. 7A to 7C may be a location where the inspection object 400 is transferred if the inspection object 400 is a good product.

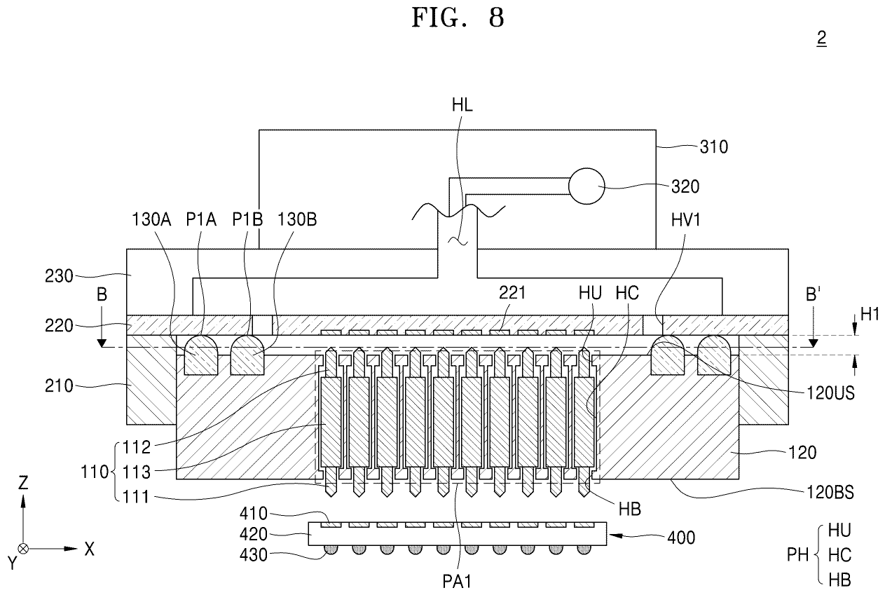

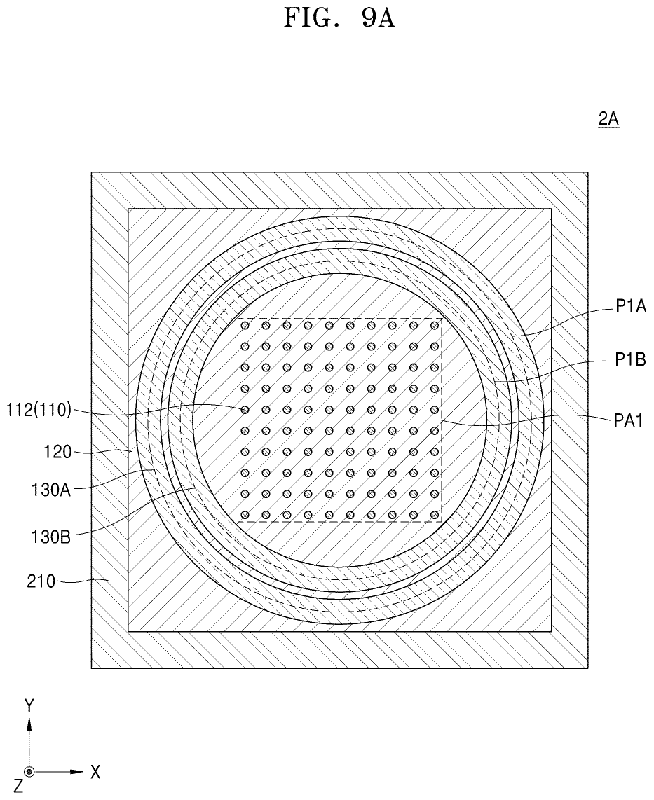

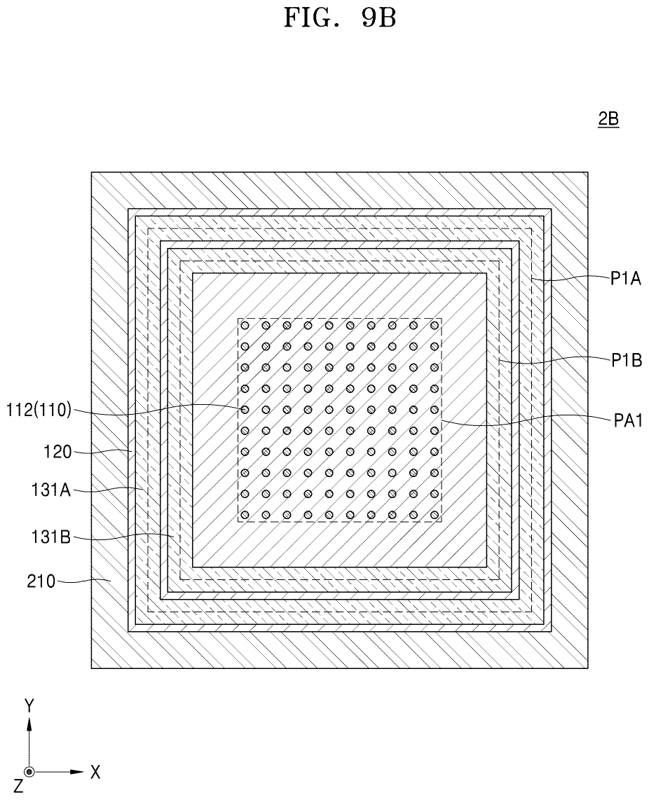

FIG. 8 is a cross-sectional view illustrating a semiconductor package inspection device 2 according to an embodiment. FIG. 9A is a plan view of a semiconductor package inspection device 2A according to an embodiment, taken along portion B-B′ of FIG. 8. Descriptions within the scope that overlap with the descriptions provided above may be omitted.

Referring to FIGS. 8 and 9A, the semiconductor package inspection device 2 and the semiconductor package inspection device 2A, which is an embodiment, may include a first sealing portion 130A and a second sealing portion 130B. An outer point P1A is a center point where the upper test board 220 and the first sealing portion 130A are in contact with each other, and an inner point P1B is a center point where the upper test board 220 and the second sealing portion 130B are in contact with each other.

A shape of the first sealing portion 130A when viewed in plan view may be a ring or circular shape around the first pin area PA1. A shape of the second sealing portion 130B in plan view may be a ring or circular shape around the first pin area PA1, and the second sealing portion 130B may be located inward relative to the first sealing portion 130A, and the first sealing portion 130A and the second sealing portion 130A may be provided in the socket block 120 in a concentric circle shape (i.e., the first sealing portion 130A and the second sealing portion 130B are concentric).

Through the first sealing portion 130A and the second sealing portion 130B, the semiconductor package inspection device 2, which is an embodiment, may be double airtight, and thus, vacuum may be maintained smoothly and reliably. Accordingly, the semiconductor package inspection device 2, which is an embodiment, may handle an inspection object stably.

FIG. 9B is a plan view of a semiconductor package inspection device 2B according to an embodiment, cut along a portion identical to portion B-B′ of FIG. 8. Descriptions within the scope that overlap with the descriptions provided above may be omitted.

The semiconductor package inspection device 2B, which is an embodiment, may include a first sealing portion 131A and a second sealing portion 131B. An outer point P1A is a center point where the upper test board 220 and the first sealing portion 131A are in contact with each other, and an inner point P1B is a center point where the upper test board 220 and the second sealing portion 131B are in contact with each other.

A shape of the first sealing portion 131A when viewed in plan view may be rectangular around the first pin area PA1. A shape of the second sealing portion 131B in plan view may be rectangular around the first pin area PA1, and the second sealing portion 131B may be located inward relative to the first sealing portion 131A, and the first sealing portion 131A and the second sealing portion 131B may be provided in the socket block 120 and spaced apart from each other at a uniform interval, as illustrated.

Through the first sealing portion 131A and the second sealing portion 131B, the semiconductor package inspection device 2B, which is an embodiment, is double airtight, and thus, vacuum may be maintained smoothly and reliably. In addition, compared to a case where the shape in plan view is a ring or circular shape, the first sealing portion 131A and the second sealing portion 131B have a rectangular shape in plan view, and a relatively small area is required for the first sealing portion 131A and the second sealing portion 131B, the semiconductor package inspection device 2B may be selected when the horizontal area of the first pin area PA1 is relatively large and a distance between the first pin area PA1 and the outer edge of the socket block 120 is relatively small.

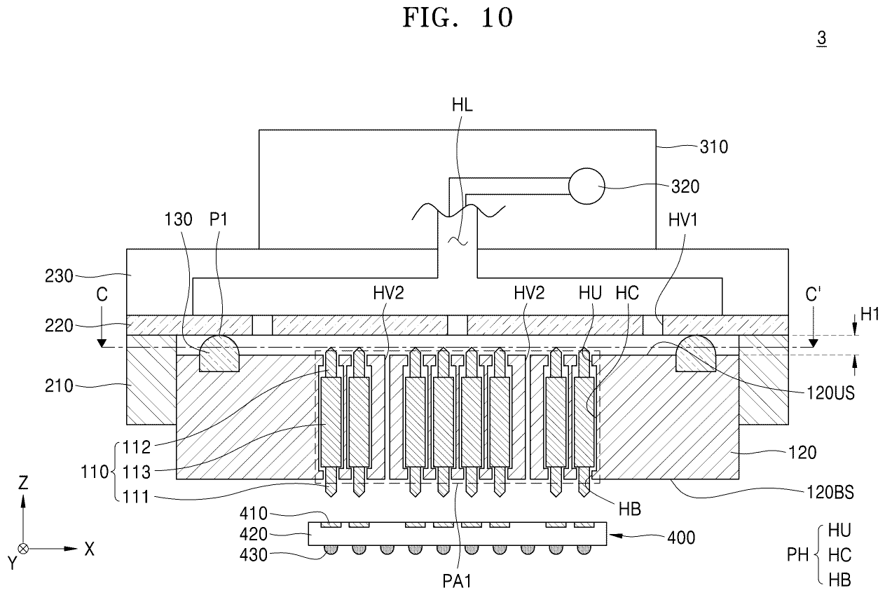

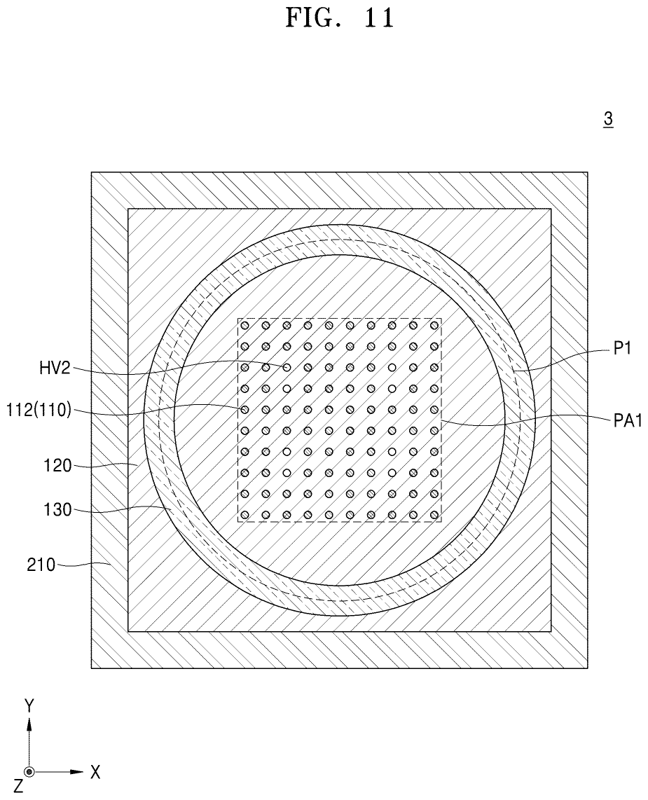

FIG. 10 is a cross-sectional view illustrating a semiconductor package inspection device 3 according to an embodiment. FIG. 11 is a plan view of the semiconductor package inspection device 3 according to an embodiment, cut along portion C-C′ of FIG. 10. Descriptions within the scope that overlap with the descriptions provided above may be omitted.

The socket block 120 of the semiconductor package inspection device 3, which is an embodiment, may include one or more vertical vacuum passageways HV2 penetrating the socket block 120. When the connection pads 410 disposed on the upper surface of the inspection object 400 are disposed leaving a portion of the upper surface of the inspection object 400 empty, the vertical vacuum passageway HV2 to be removably attached to an area of the upper surface of the inspection object 400, in which the connection pads 410 are not arranged, may be provided in the socket block 120. One or more vertical vacuum passageways HV2 may be provided inside the first pin area PA1, and the vertical vacuum passageways HV2 may supplement the vacuum that removably attaches the inspection object 400, through the plurality of pin holes PH.

For example, as illustrated in FIG. 11, eight vertical vacuum passageways HV2 may be provided in the first pin area PA1. The pogo pins 110 are not provided in the eight vertical vacuum passageways HV2, and the eight vertical vacuum passageways HV2 may be each removably attached to the area of the inspection object 400 where the connection pads 410 are not arranged, to thereby handle the inspection object 400.

Thus, the semiconductor package inspection device 3, which is an embodiment, may stably handle the inspection object 400 on which the connection pads 410 are disposed while leaving a portion of the upper surface of the inspection object 400 empty.

While the inventive concept has been particularly shown and described with reference to embodiments thereof, it will be understood by those skilled in the art that various changes in form and details may be made therein without departing from the scope of the inventive concept as defined by the appended claims. The embodiments should be considered in descriptive sense only and not for purposes of limitation.

What is claimed is:

1. A semiconductor package inspection device comprising:
a socket block;
a plurality of pin holes extending through the socket block;
a plurality of pogo pins, wherein each of the plurality of pogo pins is located within a respective one of the plurality of pin holes;
a sealing portion extending peripherally around a first pin area of the socket block, wherein the plurality of pin holes and the plurality of pogo pins are arranged in the first pin area, and wherein the sealing portion protrudes from an upper surface of the socket block;
a support socket that supports the socket block;
an upper test board on an upper surface of the support socket, wherein the upper test board comprises a plurality of first contact pads on a bottom surface thereof, and a vacuum aperture formed therethrough; and
a handler above the upper test board and comprising an internal vacuum passageway in fluid communication with the vacuum aperture,
wherein each of the plurality of pogo pins comprises a pin body, an upper pin protruding upward from the pin body, and a bottom pin protruding downward from the pin body.

2. The semiconductor package inspection device of claim 1, wherein each of the plurality of pin holes comprises an upper pin hole, a bottom pin hole, and a central pin hole in fluid communication with the upper pin hole and the bottom pin hole, and
wherein a width of the central pin hole is greater than a width of the pin body, and wherein a width of an upper pin hole and a bottom pin hole in which the upper pin and the bottom pin are located, respectively, is less than the width of the pin body.

3. The semiconductor package inspection device of claim 2, wherein a length of the pin body is less than a length of the central pin hole, and
wherein a thickness of the socket block is greater than a length from an end of the upper pin to an end of the bottom pin when the end of the upper pin and the end of the bottom pin are not in contact with each other.

4. The semiconductor package inspection device of claim 3, wherein a maximum value of a height of the end of the upper pin protruding from the upper surface of the socket block is less than a height of the sealing portion in an undeformed state.

5. The semiconductor package inspection device of claim 3, wherein, when a distance between the bottom surface of the upper test board and the upper surface of the socket block is equal to a height of the sealing portion in an undeformed state, the upper pin does not contact the upper test board.

6. The semiconductor package inspection device of claim 4, wherein a height of the sealing portion in a deformed state is less than the height of the sealing portion in the undeformed state, and
wherein the height of the end of the upper pin protruding from the upper surface of the socket block when the sealing portion in the deformed state is equal to the height of the sealing portion in the deformed state.

7. The semiconductor package inspection device of claim 6, wherein the height of the sealing portion in the undeformed state is about 0.5 mm to about 2 mm, and the height of the sealing portion in the deformed state is about 0.2 mm to about 1.5 mm.

8. The semiconductor package inspection device of claim 6, wherein a difference between the width of the central pin hole and the width of the pin body is about 0.05 mm to about 0.2 mm, and
wherein a difference between a width of each of the upper pin and the bottom pin and the width of each of the upper pin hole and the bottom pin hole is about 0.05 mm to about 0.2 mm.

9. The semiconductor package inspection device of claim 6, wherein the sealing portion comprises an elastic material.

10. The semiconductor package inspection device of claim 6, wherein the sealing portion has a ring shape when viewed in a plan view, and
wherein the sealing portion is convexly rounded and protrudes toward the upper test board in a cross-sectional view.

11. The semiconductor package inspection device of claim 6, wherein the sealing portion comprises a first sealing portion and a second sealing portion, and
wherein the first sealing portion is between an outer edge of the socket block and the second sealing portion, and wherein the second sealing portion is located between the first sealing portion and the first pin area.

12. The semiconductor package inspection device of claim 11, wherein the first sealing portion and the second sealing portion each have a ring shape when viewed in a plan view, and wherein each of the first sealing portion and the second sealing portion is convexly rounded and protrudes toward the upper test board when viewed in a cross-sectional view.

13. The semiconductor package inspection device of claim 6, wherein the sealing portion is configured to maintain contact with the bottom surface of the upper test board.

14. The semiconductor package inspection device of claim 6, further comprising a vacuum passageway within the socket block in the first pin area, and wherein the vacuum passageway does not include a pogo pin.

15. The semiconductor package inspection device of claim 6, wherein the handler is configured to provide horizontal movement, vertical movement, and rotational movement to the semiconductor package inspection device.

16. A semiconductor package inspection device comprising:
a socket block;
a plurality of pin holes extending through the socket block;
a plurality of pogo pins, wherein each of the plurality of pogo pins is located within a respective one of the plurality of pin holes;
a sealing portion extending peripherally around a first pin area of the socket block, wherein the plurality of pin holes and the plurality of pogo pins are arranged in the first pin area, and wherein the sealing portion protrudes from an upper surface of the socket block;
a support socket in contact with the socket block and configured to move the socket block in a vertical direction;
an upper test board on an upper surface of the support socket, wherein the upper test board comprises a plurality of first contact pads on a bottom surface thereof, and a vacuum aperture formed therethrough; and
a handler above the upper test board and comprising an internal vacuum passageway in fluid communication with the vacuum aperture,
wherein each of the plurality of pogo pins comprises a pin body, an upper pin protruding upward from the pin body, and a bottom pin protruding downward from the pin body, and
wherein the sealing portion has a rectangular shape when viewed in a plan view.

17. The semiconductor package inspection device of claim 16, wherein the sealing portion is convexly rounded and protrudes toward the upper test board in a cross-sectional view.

18. The semiconductor package inspection device of claim 16, wherein the sealing portion has a tapered shape with a width that decreases away from the socket block in a cross-sectional view.

19. The semiconductor package inspection device of claim 16, wherein the sealing portion comprises a first sealing portion and a second sealing portion,
wherein the first sealing portion has a rectangular shape when viewed in a plan view and is located between an outer edge of the socket block and the second sealing portion, and
wherein the second sealing portion has a rectangular shape when viewed in the plan view and is located between the first sealing portion and the first pin area.

20. A semiconductor package inspection device comprising:
a socket block;
a plurality of pin holes extending through the socket block;
a plurality of pogo pins, wherein each of the plurality of pogo pins is located within a respective one of the plurality of pin holes;
a sealing portion extending peripherally around a first pin area of the socket block, wherein the plurality of pin holes and the plurality of pogo pins are arranged in the first pin area, and wherein the sealing portion protrudes from an upper surface of the socket block;
a support socket in contact with the socket block and configured to move the socket block in a vertical direction;
an upper test board on an upper surface of the support socket, wherein the upper test board comprises a plurality of first contact pads on a bottom surface thereof, and a vacuum aperture formed therethrough; and
a handler above the upper test board and comprising an internal vacuum passageway in fluid communication with the vacuum aperture,
wherein each of the plurality of pogo pins comprises a pin body, an upper pin protruding upward from the pin body, and a bottom pin protruding downward from the pin body,
wherein each of the plurality of pin holes comprises an upper pin hole, a bottom pin hole, and a central pin hole in fluid communication with the upper pin hole and the bottom pin hole, wherein a width of the central pin hole is greater than a width of the pin body, and wherein a width of each of the upper pin hole and the bottom pin hole in which the upper pin and the bottom pin are respectively located, is less than the width of the pin body,
wherein a length of the pin body is less than a length of the central pin hole, and wherein a thickness of the socket block is less than a length from an end of the upper pin to an end of the bottom pin when the end of the upper pin and the end of the bottom pin are not in contact with each other,
wherein a maximum value of a height of the end of the upper pin protruding from the upper surface of the socket block is less than a height of the sealing portion in an undeformed state,
wherein a height of the sealing portion in a deformed state is less than the height of the sealing portion in the undeformed state, and wherein the height of the end of the upper pin protruding from the upper surface of the socket block when the sealing portion is in the deformed state is equal to the height of the sealing portion in the deformed state, and
wherein the sealing portion comprises an elastic material and has a ring shape when viewed in a plan view, wherein the sealing portion is convexly rounded and protrudes toward the upper test board in a cross-sectional view, and wherein the sealing portion is configured to maintain contact with the bottom surface of the upper test board.
